(19) United States
(12) Patent Application Publication
(10) Pub. No.: US 2022/0336295 A1
(43) Pub. Date: Oct. 20, 2022

(54) MANUFACTURING METHOD OF GROUP III-V SEMICONDUCTOR PACKAGE

(71) Applicant: Taiwan Semiconductor Manufacturing Company, Ltd., Hsinchu (TW)

(72) Inventors: Yi-An Lai, Hsinchu (TW); Chan-Hong Chern, Palo Alto, CA (US); Chih-Hua Wang, Hsinchu City (TW); Chu-Fu Chen, Hsinchu County (TW); Kun-Lung Chen, Hsinchu County (TW)

(73) Assignee: Taiwan Semiconductor Manufacturing Company, Ltd., Hsinchu (TW)

(21) Appl. No.: 17/475,379

(22) Filed: Sep. 15, 2021

Related U.S. Application Data
(60) Provisional application No. 63/175,542, filed on Apr. 15, 2021.

(51) Int. Cl. H01L 21/66; H01L 21/784; H01L 29/66

(52) U.S. Cl. CPC H01L 22/20; H01L 21/784; H01L 29/66462

(57) ABSTRACT

A manufacturing method of group III-V semiconductor package is provided. The manufacturing method includes the following steps. A wafer comprising group III-V semiconductor dies therein is provided. A chip probing (CP) process is performed to the wafer to determine reliabilities of the group III-V semiconductor dies, wherein the CP process comprises performing a multi-step breakdown voltage testing process to the group III-V semiconductor dies to obtain a first portion of dies of the group III-V semiconductor dies with breakdown voltages to be smaller than a predetermined breakdown voltage. A singulation process is performed to separate the group III-V semiconductor dies from the wafer. A package process is performed to form group III-V semiconductor packages including the group III-V semiconductor dies. A final testing process is performed on the group III-V semiconductor packages.

### CROSS-REFERENCE TO RELATED APPLICATION

This application claims the priority benefit of U.S. provisional application Ser. No. 63/175,542, filed on Apr. 15, 2021. The entirety of the above-mentioned patent application is hereby incorporated by reference herein and made a part of this specification.

### BACKGROUND

Semiconductor devices based on silicon have been the standard for the past few decades. However, semiconductor devices based on alternative materials are receiving increasing attention for advantages over silicon-based semiconductor devices. For example, semiconductor devices based on group III-V semiconductor materials have been receiving increased attention due to high electron mobility and wide band gaps compared to silicon-based semiconductor devices. Such high electron mobility and wide band gaps allow improved performance and high temperature applications. However, there may be significant lattice mismatch between GaN and the substrate, which may produce many crystal defects in the devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an exemplary wafer structure with scribe streets in accordance with some embodiments of the present disclosure.

FIG. 2 is a schematic cross-sectional view of a portion of the wafer structure of FIG. 1 in accordance with some embodiments of the present disclosure.

FIG. 3 is an exemplary flow chart showing the process steps of a packaging method in accordance with some embodiments of the present disclosure.

FIG. 4 illustrates an exemplary breakdown voltage distribution of the semiconductor wafer as illustrated in FIG. 1 and FIG. 2.

FIG. 5 illustrates an exemplary Idlin variation distribution of the semiconductor wafer as illustrated in FIG. 1 and FIG. 2.

FIG. 6 illustrates exemplary relationship curves between substrate currents and drain voltages of the group III-V semiconductor dies as illustrated in FIG. 1 and FIG. 2.

FIG. 7 illustrates exemplary relationship curves between gate currents and gate voltages of two group III-V semiconductor dies as illustrated in FIG. 1 and FIG. 2.

FIG. 8 illustrates exemplary relationship curves of cutoff currents and drain voltages of two group III-V semiconductor dies as illustrated in FIG. 1 and FIG. 2.

FIG. 9 illustrates exemplary relationship curves of drain currents and drain voltages of two group III-V semiconductor dies as illustrated in FIG. 1 and FIG. 2.

FIG. 10 illustrates an exemplary relationship curves of cutoff currents of a group III-V semiconductor die as illustrated in FIG. 1 and FIG. 2.

FIG. 11 illustrates calculated first derivatives and second derivatives of the group III-V semiconductor dies as illustrated in FIG. 1 and FIG. 2.

FIG. 12A is a schematic cross-sectional view of a portion of the wafer structure after a first laser grooving process in accordance with some embodiments of the present disclosure.

FIG. 12B is a schematic cross-sectional view of a portion of the wafer structure after a second laser grooving process in accordance with some embodiments of the present disclosure.

FIG. 12C is a schematic cross-sectional view of a portion of the wafer structure after a mechanical dicing process in accordance with some embodiments of the present disclosure.

FIG. 13 is a schematic cross-sectional view of a semiconductor package in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The embodiments are intended to provide further explanations but are not used to limit the scope of the present disclosure.

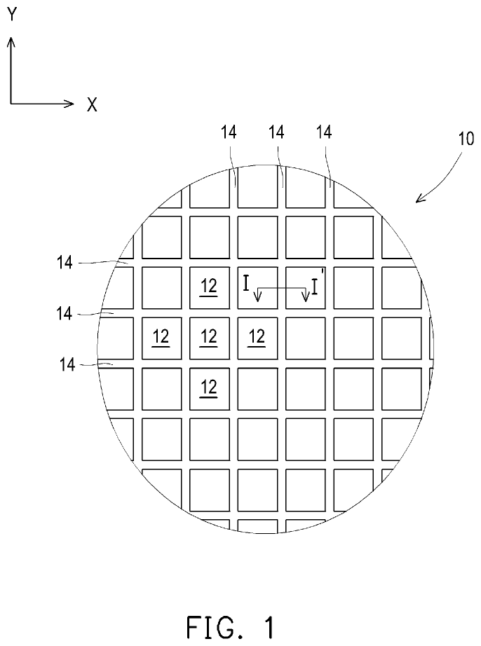

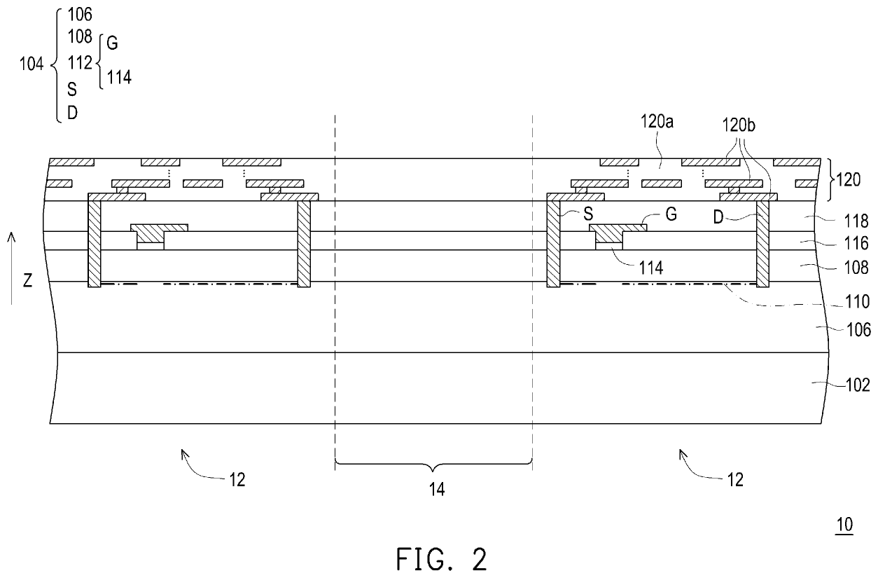

FIG. 1 illustrates a schematic top view of an exemplary wafer structure with scribe streets in accordance with some embodiments of the present disclosure. FIG. 2 illustrates a schematic cross-sectional view of a portion of the wafer structure of FIG. 1 along the cross-sectional line I-I′ in accordance with some embodiments of the present disclosure.

Referring to FIG. 1 and FIG. 2, a semiconductor wafer 10 includes a plurality of group III-V semiconductor dies 12 arranged in an array, and the adjacent group III-V semiconductor dies 12 are separated from one another by scribe streets 14. That is to say, the scribe streets 14 are formed on the exterior sides of the group III-V semiconductor dies 12. In certain embodiments, the semiconductor wafer 10 is a semiconductor wafer made of silicon or other semiconductor materials, such as III-V semiconductor materials. In some embodiments, as shown in FIG. 1, the group III-V semiconductor dies 12 are divided and separated from one another by some of the scribe streets 14 extending in the direction X and others of the scribe streets 14 extending in the direction Y. In some embodiments, the direction X is different from the direction Y, and the direction X is perpendicular to the direction Y. The scribe streets 14 extending in the direction X and the scribe streets 14 extending in the direction Y shown in FIG. 1 are shown to have the same width. However, the disclosure is not limited thereto. In some alternative embodiments, the scribe streets 14 extending in the direction X and the scribe streets 14 extending in the direction Y may have different widths.

During a singulation process (i.e., wafer dicing process), in some embodiments, the semiconductor wafer 10 is cut along the scribe streets 14 so as to separate the group III-V semiconductor dies 12. And, before the singulation process is performed on the semiconductor wafer 10, the group III-V semiconductor dies 12 of the semiconductor wafer 10 are connected with one another, as shown in FIG. 2.

Of course, the embodiment herein is merely for illustration, and the disclosure does not limit the number of the group III-V semiconductor dies 12 and/or the configuration of the semiconductor wafer 10. In some embodiments, those skilled in the art can understand that the number of the group III-V semiconductor dies 12 may be more than or less than what is depicted in FIG. 1, and may be designated based on demand and/or design layout. In some embodiments, the semiconductor wafer 10 includes other elements not depicted in FIG. 1, such as seal ring structures located between the group III-V semiconductor dies 12 and the scribe streets 14 and used as a protective wall for protecting the group III-V semiconductor dies 12 from stress, and/or test pads used for performing a wafer testing process (described hereinafter) on the semiconductor wafer 10. The seal ring structures are configured to protect the group III-V semiconductor dies 12 from stress and prevent cracks generated during singulation process (described hereinafter) from propagating into the group III-V semiconductor dies 12.

In some embodiments, as shown in FIG. 2, the group III-V semiconductor die 12 of the semiconductor wafer 10 includes a semiconductor device 104 formed on a substrate 102. In some embodiments, the substrate 102 is or comprises silicon. For example, the substrate 102 may be or comprise monocrystalline silicon or some other suitable silicon material. In some embodiments, the substrate 102 is devoid of group III-V semiconductor materials. In some embodiments, the substrate 102 is a silicon carbide substrate, a sapphire substrate or a low lattice mismatch substrate.

During the semiconductor manufacturing processes of the semiconductor wafer 10, the semiconductor device 104 is fabricated during the front-end-of-line (FEOL) processes. In some embodiments, as shown in FIG. 2, the semiconductor device 104 includes a channel layer 106 and a barrier layer 108. The channel layer 106 includes a channel region 110 (demarcated by the dashed line), within which a conductive channel is selectively formed. The channel layer 106 is or otherwise includes a semiconductor material, such as a group III-V semiconductor material. In some embodiments, the channel layer 106 is or otherwise includes GaN. In alternative embodiments, the channel layer 106 is or otherwise includes AlGaN, AlN or indium gallium nitride (InGaN). In some embodiments, the channel layer 106 is epitaxially grown over the substrate 102. In some embodiments, the thickness of the channel layer 106 ranges from about 1 micrometer to about 10 micrometers. The channel layer 106 is typically un-doped, but it can be doped intentionally or unintentionally (e.g., unintentionally from process contaminants). Further, where doped, the channel layer 106 is typically doped with an n-type dopant.

The barrier layer 108 is located on the channel layer 106. In some embodiments, as shown in FIG. 2, the barrier layer 108 is located directly on the channel layer 106, such that the top surface of the channel layer 106 and the bottom surface of the barrier layer 108 abut each other. The barrier layer 108 is or otherwise includes a semiconductor material, such as a group III-V semiconductor material. In detail, the barrier layer 108 includes a material having a band gap unequal to (e.g., larger than) that of the channel layer 106. In some embodiments, the group III-V semiconductor material of the barrier layer 108 is different the group III-V semiconductor material of the channel layer 106. For example, the barrier layer 108 includes a thin film of AlGaN having a band gap that is larger than the band gap of the channel layer 106 having a thin film of GaN (AlGaN has a band gap of approximately 4 electron Volts (eV), while GaN has a band gap of approximately 3.4 eV). In some embodiments, the barrier layer 108 is intentionally doped with n-type doping. Further, in some embodiments, the barrier layer 108 includes about 5% to about 40% aluminum. In some embodiments, the method of forming the barrier layer 108 includes performing an epitaxial growth process. In some embodiments, the thickness of the barrier layer 108 ranges from about 6 nanometers to about 30 nanometers.

The barrier layer 108 and the channel layer 106 collectively define a heterojunction at the interface at which the channel layer 106 and the barrier layer 108 directly contact. Hence, the channel layer 106 and the barrier layer 108 collectively referred to as a group III-V heterojunction structure. The heterojunction allows the barrier layer 108 to selectively provide or remove electrons to or from a 2-DEG in the channel region 110 along the interface between the channel layer 106 and the barrier layer 108. The 2-DEG has high mobility electrons that are not bound to any atoms and free to move within the 2-DEG. With a high concentration of electrons from the barrier layer 108, the 2-DEG serves as the conductive channel for the semiconductor device 104. This provides for higher transistor mobility as compared with other types of transistors. Therefore, the semiconductor device 104 is often referred to as high-electron mobility transistor (HEMT) device. In some embodiments, the semiconductor device 104 may be an enhancement mode HEMT device or a depletion mode HEMT device. In some embodiments, the thickness of the group III-V heterojunction structure (including the channel layer 106 and the barrier layer 108) ranges from about 1 micrometers to about 10 micrometers.

In some embodiments, as shown in FIG. 2, the semiconductor device 104 further includes a gate structure 112, a source S and a drain D. The gate structure 112 includes a polarization modulation portion 114 and a gate G. The polarization modulation portion 114 of a gate structure 112 is located over a gate region of the barrier layer 108. In some embodiments, as shown in FIG. 2, the polarization modulation portion 114 is arranged in direct contact with the barrier layer 108, such that the bottom surface of the polarization modulation portion 114 abuts the top surface of the barrier layer 108. The doping and material selected for the polarization modulation portion 114 partially sets the threshold voltage of the semiconductor device 104 (e.g., by raising the conduction band energy and reducing the conduction band to Fermi level energy). For example, dimensions and material properties can be adjusted to set the threshold voltage. Further, the polarization modulation portion 114 is configured to form a cut-off region of the 2-DEG or a region with a relatively low electron density. In some embodiments, the polarization modulation portion 114 includes a group III-V semiconductor material with a high work function. In some embodiments, the group III-V semiconductor material of the polarization modulation portion 114 includes GaN having a doping type. In alternative embodiments, the group III-V semiconductor material 1 of the polarization modulation portion 114 includes AlGaN or InGaN having the doping type. The doping type is, for example, a p-type doping, an n-type doping, or both a p-type and n-type doping. In certain embodiments, the group III-V semiconductor material of the polarization modulation portion 114 includes GaN doped with a P-type dopant (such as Mg). In some embodiments, the polarization modulation portion 114 has a thickness from about 15 nanometers to about 150 nanometers, and has about 1% to about 20% of P-type dopant (such as Mg). In some embodiments, the method for forming the polarization modulation portion 114 includes forming a photoresist layer over a polarization modulation material layer, patterning the photoresist layer, applying an etchant to the polarization modulation material layer using the patterned photoresist layer as a mask, and removing the patterned photoresist layer. In some embodiments, the method of forming the polarization modulation material layer includes performing an epitaxial growth process.

The gate G of the gate structure 112 is arranged on the polarization modulation portion 114. In some embodiments, as shown in FIG. 2, the gate G is arranged in direct contact with the polarization modulation portion 114, such that the bottom surface of the gate G abuts the top surface of the polarization modulation portion 114. However, the disclosure is not limited thereto. In some alternative embodiments, the gate G is arranged over the polarization modulation portion 114, and not in direct contact with the polarization modulation portion 114. For example, a gate protection layer is arranged between the gate G and the polarization modulation portion 114, and the thickness of the gate protection layer is sufficient to protect the polarization modulation portion 114 from damage, such as etch damage or contamination, that could otherwise occur during processing, and as such helps to prevent leakage current in the final semiconductor device 104, while the gate protection layer is thin enough so that it doesn't inhibit the electrical coupling (e.g., ohmic coupling) of the gate G to the polarization modulation portion 114. Further, the gate G includes a conductive material, such as a metal. Examples of metals suitable for use with the gate G include titanium, nickel, aluminum, or gold. In some embodiments, the metal suitable for use in the gate G has high work function. In some embodiments, the method of forming the gate G may include electroplating, deposition, and/or photolithography and etching.

Although FIG. 2 illustrates that the gate structure 112 includes the polarization modulation portion 114 and the gate G, the embodiment herein is merely for illustration, and the disclosure does not limit the configuration of the gate structure 112. In alternative embodiments, the polarization modulation portion 114 is omitted, i.e., the gate structure 112 only includes the gate G. In such embodiments, the gate G is arranged in direct contact with the barrier layer 108, such that the bottom surface of the gate G abuts the top surface of the barrier layer 108. And, in such embodiments, the gate G may include a material which can form a Schottky contact with the group III-V semiconductor material of the barrier layer 108 so as to form the depletion region at the interface at which the gate structure 112 and the barrier layer 108 directly contact.

The source S and a drain D are arranged on opposite sides of the gate structure 112 over the channel region 110. In some embodiments, as shown in FIG. 2, the source S and the drain D extend through the barrier layer 108 and into the channel region 110. However, the disclosure is not limited thereto. In some alternative embodiments, the source S and the drain D may contact the top surface of the barrier layer 108 or extend into the barrier layer 108 without extending through the barrier layer 108. In some embodiments, as shown in FIG. 2, the gate structure 112 is arranged closer to the drain D than the source S. However, the disclosure is not limited thereto. In some alternative embodiments, the gate structure 112 may be spaced equally from the source D and the drain D. Each of the source S and the drain D includes a conductive material, such as a metal or a material which forms an ohmic contact with a group III-V semiconductor material. Examples of metals suitable for use with the source S and the drain D include titanium, nickel, aluminum, or gold. In some embodiments, the method of forming the source S and the drain D may include electroplating, deposition, and/or photolithography and etching.

In some embodiments, as shown in FIG. 2, the group III-V semiconductor die 12 of the semiconductor wafer 10 further includes a passivation layer 116 and a dielectric layer 118 over the substrate 102. The passivation layer 116 is arranged over the barrier layer 108, typically in direct contact with the barrier layer 108, such that the bottom surface of the passivation layer 116 abuts the top surface of the barrier layer 108. In some embodiments, the passivation layer 116 is or otherwise includes silicon nitride or silicon oxide. In some embodiments, the method of forming the passivation layer 116 includes physical vapor deposition (PVD), chemical vapor deposition (CVD), plasma-enhanced CVD (PECVD) or the like. In some embodiments, the thickness of the passivation layer 116 ranges from about 0.1 micrometers to about 5 micrometers.

In some embodiments, as shown in FIG. 2, the gate structure 112 extends vertically from over the passivation layer 116, through the passivation layer 116, and to the barrier layer 108. Further, in some embodiments, the gate structure 112 has a T-shaped profile, in which an upper bottom surface of the gate structure 112 directly abuts the top surface of the passivation layer 116, and the lower bottom surface of the gate structure 112 directly abuts the top surface of the barrier layer 108. However, the embodiment herein is merely for illustration, and the disclosure does not limit the configuration of the gate structure 112. In alternative embodiments, the sidewall of the polarization modulation portion 114 extends laterally past the sidewall of the gate G surrounded by the passivation layer 116, and the gate structure 112 has an I-shaped profile.

As shown in FIG. 2, the dielectric layer 118 is arranged over the passivation layer 116 and in direct contact with the passivation layer 116, such that the bottom surface of the dielectric layer 118 abuts the top surface of the passivation layer 116. In some embodiments, the dielectric layer 118 is or otherwise includes silicon nitride or silicon oxide. In some embodiments, the method of forming the dielectric layer 118 includes PVD, CVD, PECVD or the like. In some embodiments, the thickness of the dielectric layer 118 ranges from about 1 micrometer to about 10 micrometers.

In some embodiments, as shown in FIG. 2, the source S and the drain D also extend vertically through the dielectric layer 118 and the passivation layer 116. However, the embodiment herein is merely for illustration, and the disclosure does not limit the configuration of each of the source S and the drain D. In alternative embodiments, the source S and the drain D may each have a T-shaped profile, in which upper bottom surfaces of the source S and the drain D directly abut the top surface of the passivation layer 116 and lower bottom surfaces of the source S and the drain D directly contact the barrier layer 108 or the channel layer 106.

In some embodiments, as shown in FIG. 2, the group III-V semiconductor die 12 of the semiconductor wafer 10 further includes an interconnection structure 120 over the substrate 102. During the semiconductor manufacturing processes of the semiconductor wafer 10, the interconnection structure 120 is fabricated during the back-end-of-line (BEOL) processes. In some embodiments, the interconnection structure 120 is electrically connected with the semiconductor device 104. In some embodiments, the interconnection structure 120 includes an inter-dielectric layer 120a and a plurality of conductive layers 120b. In some embodiments, the conductive layers 120b are embedded in the inter-dielectric layer 120a. For simplicity, the inter-dielectric layer 120a is illustrated as a bulky layer in FIG. 2, but it should be understood that the inter-dielectric layer 120a may be constituted by multiple dielectric layers, and the number of the dielectric layers in the inter-dielectric layer 120a may be adjusted depending on product requirement. Further, the conductive layers 120b and the dielectric layers of the inter-dielectric layer 120a may be stacked alternately. It should be noted that the number of the conductive layers 120b shown in FIG. 2 is merely an illustration, and the disclosure is not limited. In some alternative embodiments, the number of the conductive layers 120b may be adjusted based on product requirement. In some embodiments, the conductive layers 120b include metal lines, vias, contact plugs or the combinations thereof.

In some embodiments, the inter-dielectric layer 120a may be made of fragile material. In some embodiments, the fragile material may include a low-k dielectric material having a k-value of less than about 3. For example, the inter-dielectric layer 120a may be made of a low-k dielectric material having a k-value of less than about 2.5, and hence is sometimes referred to as an extra low-k (ELK) dielectric layer. In some embodiments, examples of the low-k dielectric material may include hydrogen silsesquioxane (HSQ), porous HSQ, methyl silsesquioxane (MSQ), porous MSQ, NANOGLASS®, hybrid-organo siloxane polymer (HOSP), CORAL®, AURORA®, BLACK DIAMOND®, Xerogel, Aerogel, amorphous fluorinated carbon, Parylene, BCB, FLARE®, SILK®, SiOF, or the like. In some embodiments, the inter-dielectric layer 120a is formed by suitable fabrication techniques such as spin-on coating, CVD, High-Density Plasma CVD (HDPCVD) or PECVD. In some embodiments, the conductive layers 120b are made of aluminum, aluminum alloy, copper, copper alloy, tungsten, combinations thereof, or other suitable material. In some embodiments, the conductive layers 120b are formed by suitable fabrication techniques such as electroplating or deposition. In certain embodiments, the conductive layers 120b are formed by dual-damascene process. In alternative embodiments, the conductive layers 104b are formed by multiple single damascene processes.

Although FIG. 2 illustrates that the semiconductor device 104 includes the channel layer 106, the barrier layer 108, the gate structure 112, the source S and the drain D, the embodiment herein is merely for illustration, and the disclosure does not limit the configuration of the semiconductor device 104. In alternative embodiments, the semiconductor device 104 may further include at least one buffer layer, at least one field plate and/or at least one gate protection layer. In some embodiments, the buffer layer may be disposed between the substrate 102 and the channel layer 106. The buffer layer is configured to alleviate a lattice constant difference and a thermal expansion coefficient difference between the substrate 102 and the channel layer 106. As such, the at least one buffer layer can have lattice constant that transition between the lattice constant of the substrate 102 and the lattice constant of the channel layer 106. In some embodiments, the buffer layer is or otherwise includes a semiconductor material, such as a group III-V semiconductor material. In certain embodiments, the material of the buffer layer includes MN, GaN, AlGaN, InGaN, AlInN, AlGaInN or a combination thereof. The field plate is configured to effectively disperse the aggregation effect of high electric field from high voltage side (e.g., drain D). In some embodiments, the field plate may be disposed in the channel layer 106, on or over the barrier layer 108. In some embodiments, the gate protection layer may be disposed between the polarization modulation portion 114 and the gate G. The gate protection layer is configured to protect the polarization modulation portion 114 from damage, such as etch damage or contamination, and as such helps to prevent leakage current. In some embodiments, the gate protection layer is or otherwise includes aluminum nitride, aluminum oxide and/or a material resistive to ammonium hydroxide.

It should be noted that although one semiconductor device 104 is illustrated in FIG. 2, the number of the semiconductor device 104 is not limited in this disclosure. In some alternative embodiments, the group III-V semiconductor die 12 may include more than one semiconductor device 104, and the number may be designated based on demand and/or design layout.

Further, FIG. 2 illustrates that the group III-V semiconductor die 12 includes the semiconductor device 104, the embodiment herein is merely for illustration, and the disclosure does not limit the configuration of the group III-V semiconductor die 12. In alternative embodiments, the group III-V semiconductor die 12 may further include other various passive and active devices, such as resistors, capacitors, inductors, diodes, memory devices, sensors, or other types of transistor different from HEMT device.

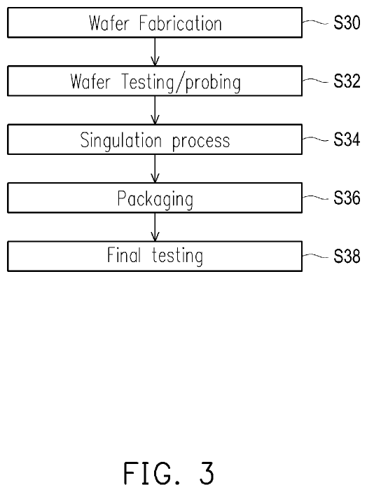

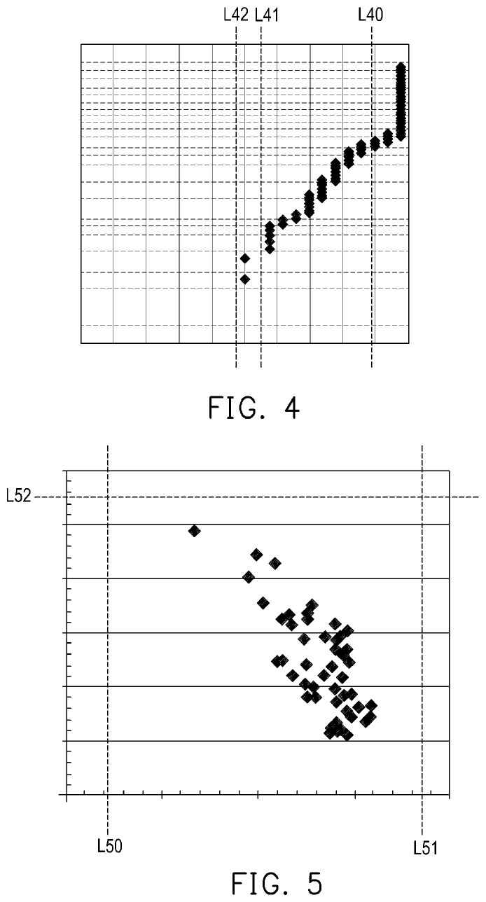

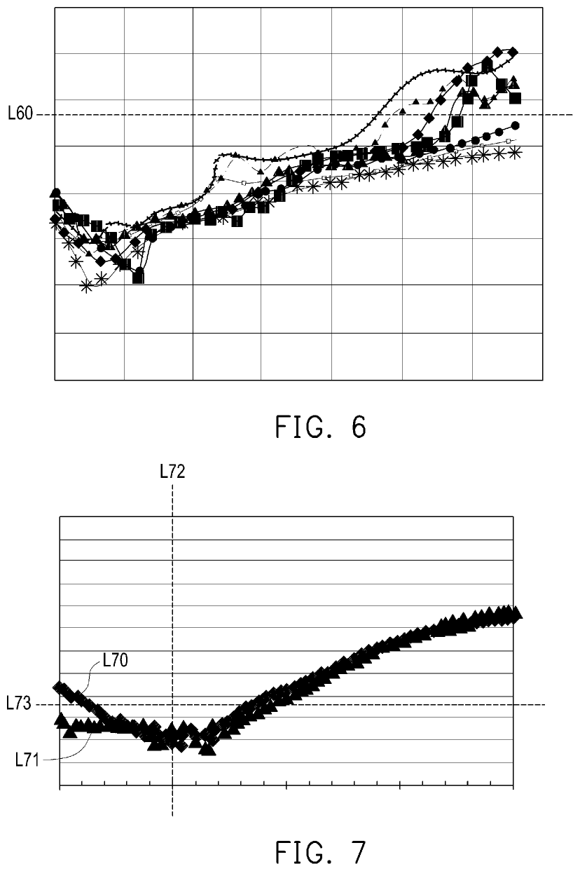

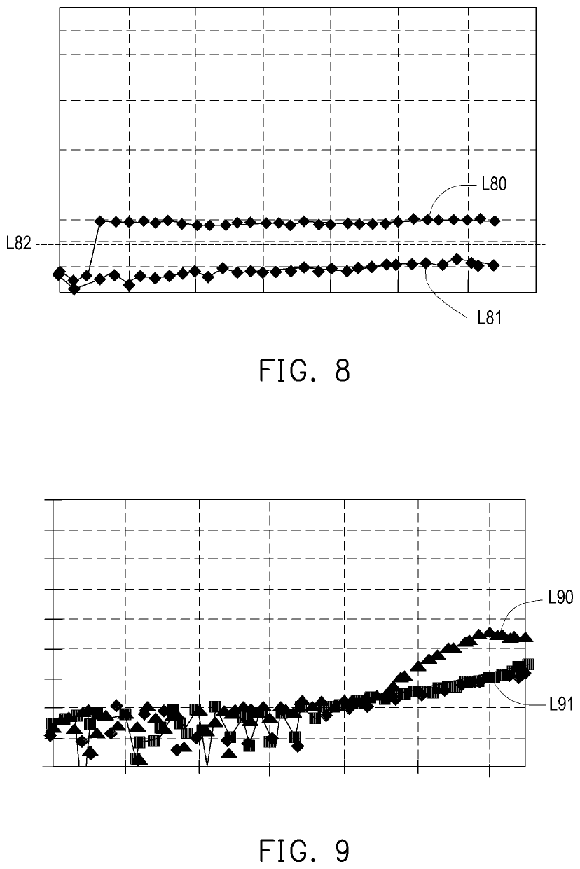

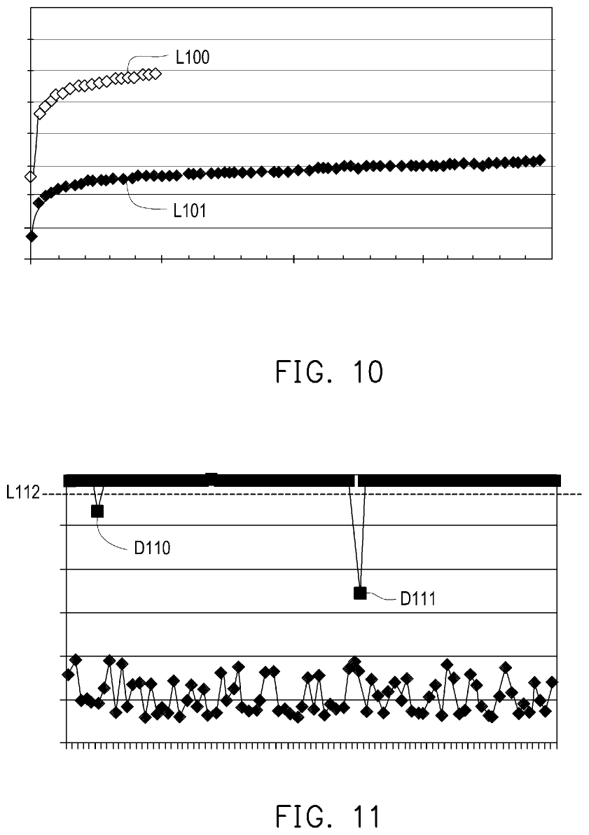

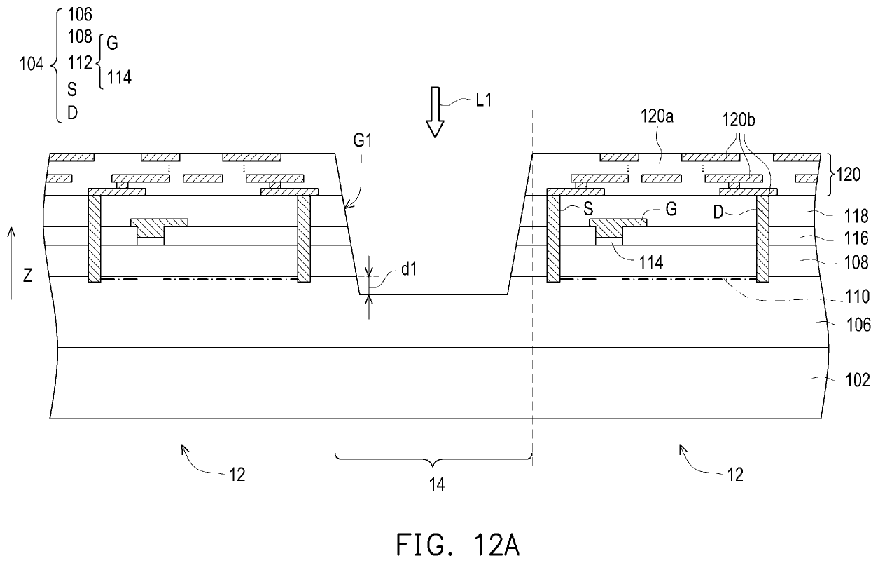

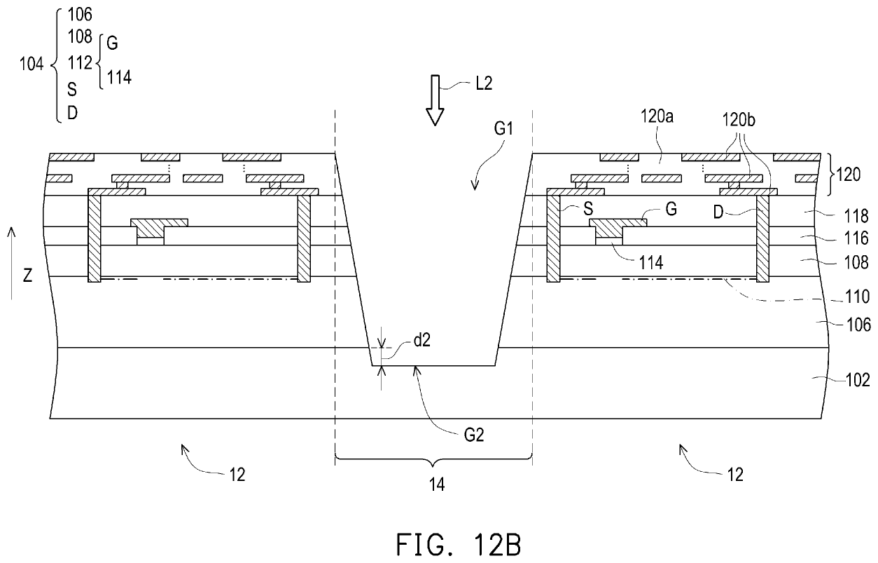

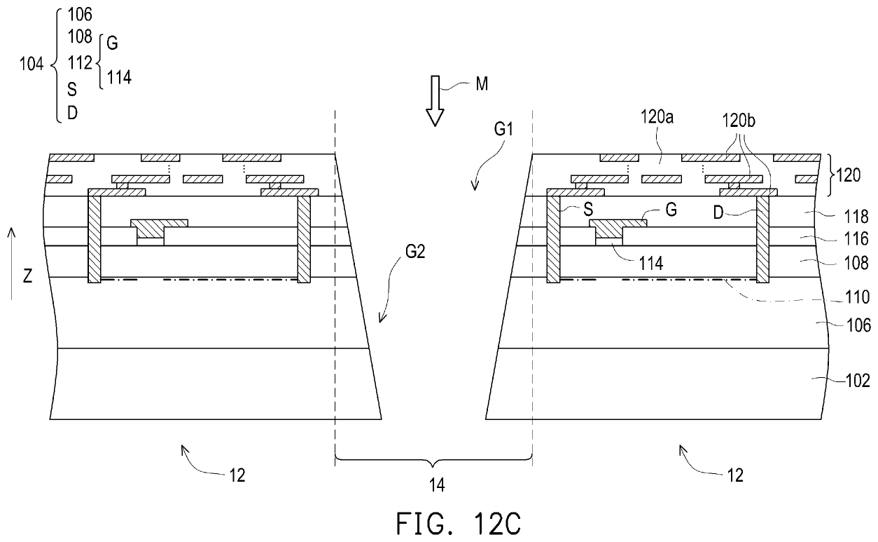

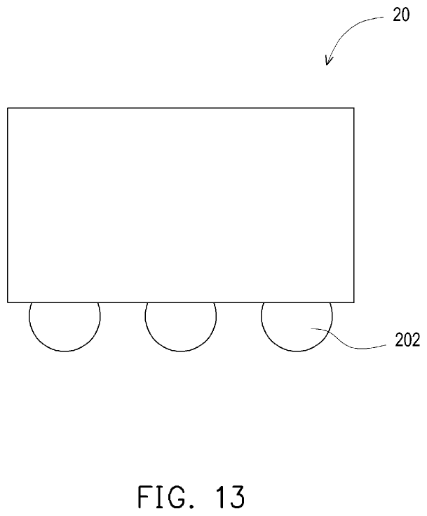

FIG. 3 is an exemplary flow chart showing the process steps of a packaging method in accordance with some embodiments of the present disclosure. FIG. 4 illustrates an exemplary breakdown voltage distribution of a semiconductor wafer 10 as illustrated in FIG. 1 and FIG. 2. FIG. 5 illustrates exemplary an exemplary Idlin variation distribution of a semiconductor wafer 10 as illustrated in FIG. 1 and FIG. 2. FIG. 6 illustrates exemplary relationship curves between substrate currents and drain voltages of the group III-V semiconductor dies 12 as illustrated in FIG. 1 and FIG. 2. FIG. 7 illustrates exemplary relationship curves between gate currents and gate voltages of two group III-V semiconductor dies 12 as illustrated in FIG. 1 and FIG. 2. FIG. 8 illustrates exemplary relationship curves of cutoff currents and drain voltages of two group III-V semiconductor dies 12 as illustrated in FIG. 1 and FIG. 2. FIG. 9 illustrates exemplary relationship curves of drain currents and drain voltages of two group III-V semiconductor dies 12 as illustrated in FIG. 1 and FIG. 2. FIG. 10 illustrates an exemplary relationship curves of cutoff currents of a group III-V semiconductor die 12 as illustrated in FIG. 1 and FIG. 2. FIG. 11 illustrates calculated first derivatives and second derivatives of the group III-V semiconductor dies 12 as illustrated in FIG. 1 and FIG. 2. FIG. 12A is a schematic cross-sectional view of a portion of the wafer structure after a first laser grooving process in accordance with some embodiments of the present disclosure. FIG. 12B is a schematic cross-sectional view of a portion of the wafer structure after a second laser grooving process in accordance with some embodiments of the present disclosure. FIG. 12C is a schematic cross-sectional view of a portion of the wafer structure after a mechanical dicing process in accordance with some embodiments of the present disclosure. FIG. 13 is a schematic cross-sectional view of a semiconductor package in accordance with some embodiments of the present disclosure. Referring to FIG. 3 and FIGS. 1-2, in step S30, the semiconductor wafer 10 is provided and subjected to various manufacturing processes, such as front-end-of-line (FEOL) processes and/or the back-end-of-line (BEOL) processes for wafer fabrication. In some embodiments, before performing step S32, a backside grinding process may be performed to the semiconductor wafer 10. In some embodiments, before performing step S32, a ball mounting process may be performed to mount solder bumps or solder balls onto the semiconductor wafer 10.

Referring to FIG. 3 and FIGS. 4-11, in step S32, the semiconductor wafer 10 is subjected to wafer testing process (i.e., wafer probing process or wafer-level chip probing (CP) process) to determine reliabilities of the group III-V semiconductor dies 12, and/or to recognize the reliable known good dies (KGDs) among the group III-V semiconductor dies 12.

In step S32, the CP process is applied to the semiconductor wafer 10 for determining reliabilities and/or identifying whether there are defects in each of the group III-V semiconductor dies 12. Since structures and manufacturing process of the group III-V semiconductor dies 12 are different from those of the semiconductor dies with metal-oxide-silicon (MOS) transistors, the reliability issues and defects between them are also distinct. In order to recognize reliabilities of the group III-V semiconductor dies 12 on the semiconductor wafer 10, the CP process is applied. In some embodiments, the CP process comprises at least one of a multi-step breakdown voltage test, a current leakage reliability test, a substrate leakage test, a gate trapping test, a gate barrier lowering test, a drain-source breakdown voltage (BVdss) robustness test, an access region trap test, and a BVdss acceleration test. Each of the said tests may correspond to unique reliability issue and/or defects of the semiconductor devices 104 in the group III-V semiconductor dies 12, such that the CP process is developed for high quality of the group III-V semiconductor dies 12.

In some embodiments, a multi-step breakdown voltage test may be performed to the group III-V semiconductor dies 12 to determine a portion of dies of the group III-V semiconductor dies 12. In some embodiments, the determined portion of dies may have their breakdown currents to be greater than a voltage level required by a certain system specification. In other words, the determined portion of dies may keep their current to be less than a predetermined breakdown current level within the voltage level required by system. Therefore, the determined portion of dies may be recognized as KGDs.

Specifically, in the multi-step breakdown voltage test, a first sweep signal may be applied to the drains D of the semiconductor devices 104 in the group III-V semiconductor dies 12 to determine a first portion of dies with drain currents to be smaller a predetermined breakdown current. The first sweep signal may be increased gradually up to a first voltage level. In some embodiments, the dies with drain currents to be greater than the predetermined breakdown current may be recognized as bad dies, and the first portion of dies with the drain currents to be smaller the predetermined breakdown current may be obtained. In some embodiments, the first voltage level is selected from a voltage range within 0V-1500V. The predetermined breakdown current level is selected from a current range within 10 mA-10 nA. Then, a second sweep signal may be applied to the drain D of the first portion of dies, and a second portion of dies of the group III-V semiconductor dies 12 with the drain currents to be smaller than the predetermined breakdown current is obtained. The second sweep signal may be increased gradually up to a second voltage level. In some embodiments, the second voltage level is selected from a voltage range within 300V-1500V. The first voltage level is greater than the second voltage level. Therefore, the second portion of dies which keep their drain currents to be less than the predetermined breakdown current while applying the first sweep signal and the second sweep signal are obtained. In some embodiments, the second portion of dies among the group III-V semiconductor dies 12 may be determined as KGDs.

FIG. 4 illustrates an exemplary breakdown voltage distribution of a semiconductor wafer 10 as illustrated in FIG. 1 and FIG. 2. The vertical axis is the accumulated numbers of the group III-V semiconductor dies 12, and the horizontal axis is the breakdown voltage. Therefore, the dots in FIG. 4 represent accumulated numbers of breakdown voltage distributions of the group III-V semiconductor dies 12. Lines L40-L41 are respectively the first voltage level and the second voltage level. A line L42 is a voltage level required by a certain system specification. The voltage level of the line L40 is greater than a voltage level of the line L41. The voltage level of the line L41 is greater than a voltage level of the line L42.

When the first sweep signal is applied to the group III-V semiconductor dies 12 of the semiconductor wafer 10, the dots on the left-hand side of the line L40 may be recognized as bad dies, and the dots on the right-hand side of the line L40 may be recognized as the first portion of dies. In some embodiments, the applied first sweep signal may bring negative impact on reliabilities of the first portion of dies, and thus the second sweep signal up to the second voltage level is provided to the first portion of dies to determine whether there is any die with breakdown voltage smaller than the second voltage level. Therefore, after the first sweep signal and the second sweep signal are applied to the group III-V semiconductor dies 12, the second portion of dies may be obtained. Breakdown voltage levels of the second portion of dies may be located on the right-hand side of the line L40. Therefore, the second portion of dies meet the voltage level required by system.

In some embodiments, the breakdown voltage distribution of a semiconductor wafer comprising the group III-V semiconductor dies 12 is different from that of a semiconductor wafer comprising the silicon semiconductor dies. For example, the breakdown voltages of the silicon semiconductor dies on the same semiconductor wafer may be more consistent. Therefore, it is unnecessary to examine each breakdown voltage of the silicon semiconductor dies on a same wafer.

In some embodiments, a high temperature reverse bias (HTRB) testing process may be performed to the group III-V semiconductor dies 12 to determine a portion of dies of the group III-V semiconductor dies 12. In some embodiments, the determined portion of dies may have their drain current variations to be smaller than a predetermined current variation according to results of the HTRB testing process. Therefore, the determined portion of dies may be recognized as KGDs.

Specifically, the HTRB testing process may obtain a drain current variation information of the semiconductor devices 104 in the group III-V semiconductor dies 12. In some embodiments, the HTRB may obtain a linear-region drain current (Idlin) variation information of the semiconductor devices 104 in the group III-V semiconductor dies 12. A portion of dies of the group III-V semiconductor dies 12 may be determined with the drain current variations to be within than the predetermined current variation range according to the drain current variation information.

FIG. 5 illustrates an exemplary Idlin variation distribution of a semiconductor wafer 10 as illustrated in FIG. 1 and FIG. 2. The vertical axis the first derivative of the drain current with respect to drain voltage, and the horizontal axis is variation of the Idlin. Specifically, the variation of Idlin is measured under a predetermined drain voltage. In some embodiments, the predetermined drain voltage is selected from a voltage rage within 0V-1500V. Lines L50-L52 are boundary lines of the predetermined current variation range. In some embodiments, the lines L50, L51 are respectively +30% and −30% of variation. The line L52 is the boundary line of 1 uA/V. Therefore, each dot in FIG. 5 represents an Idlin variation of each group III-V semiconductor die 12. A portion of dies of the group III-V semiconductor dies 12 between the lines L50, L51 and under the line L52 are obtained. The portion of dies may be determined to be KGDs.

In some embodiments, a substrate leakage test may be performed to the group III-V semiconductor dies 12 to obtain a portion of dies of the group III-V semiconductor dies 12. In some embodiments, the determined portion of dies may have their substrate leakage currents to be smaller than a predetermined substrate leakage current. Therefore, the determined portion of dies may be recognized as KGDs.

Specifically, in the substrate leakage test, a sweep signal may be applied to the drains D of the semiconductor devices 104 in the group III-V semiconductor dies 12, to obtain a substrate leakage current information of the group III-V semiconductor dies 12. The supplied sweep signal may be a voltage within a voltage range of 0V-1500V, to obtain the substrate leakage current information within the voltage range. Then, a portion of dies with the substrate leakage currents to be smaller than the predetermined substrate leakage current according to the substrate leakage current information may be obtained. In some embodiments, the substrate leakage may be obtained through probing the active region of the group III-V semiconductor die 12, in which the semiconductor device 104 is disposed. In some embodiments, the probing process on the active region may be performed by probing the source S, the drain D, the gate G or the probing pad connected to the active region.

FIG. 6 illustrates exemplary relationship curves between substrate currents and drain voltages of the group III-V semiconductor dies 12 as illustrated in FIG. 1 and FIG. 2. The vertical axis is the substrate currents, and the horizontal axis is the applied drain voltage of the group III-V semiconductor dies 12. A line L60 is a predetermined substrate leakage current level.

In some embodiments, if a relationship curve has a slope greater than a predetermined slope when the relationship is above the predetermined substrate leakage current, i.e., the line L60, the corresponding group III-V semiconductor dies 12 may be determined as a bad die. Other III-V semiconductor dies 12 may be determined as KGDs. In some embodiments, a portion of dies with the substrate leakage currents to be smaller than the predetermined substrate leakage current, i.e., the line L60, according to the substrate leakage current information may be determined as KGDs.

In some embodiments, a gate trapping test may be performed to the group III-V semiconductor dies 12 to determine a portion of dies of the group III-V semiconductor dies 12. In some embodiments, the determined portion of dies may have their gate currents to be smaller than a predetermined gate current when the gate G are reversed bias. Therefore, the determined portion of dies may be recognized as KGDs.

Specifically, in the gate trapping test, a sweep signal is applied to the gates G of semiconductor devices 104 in the group III-V semiconductor dies 12, to obtain a gate current information corresponding to gate currents of the semiconductor devices 104. The sweep signal may be applied to the group III-V semiconductor dies 12 to obtain corresponding gate currents. In some embodiments, the applied sweep signal may be within a voltage range of −12V to 0V. Then, a portion of dies with the gate currents to be smaller than a predetermined gate current is determined according to the gate current information. In some embodiments, the determined second portion of dies among the group III-V semiconductor dies 12 may be determined as KGDs.

FIG. 7 illustrates exemplary relationship curves between gate currents and gate voltages of two group III-V semiconductor dies 12 as illustrated in FIG. 1 and FIG. 2. The vertical axis is the gate current, and the horizontal axis is the applied gate voltage of the group III-V semiconductor dies 12. Lines 70, 71 are the relationship curve of two different group III-V semiconductor dies 12. Line 72 is an upper boundary of the sweep signal applied to the gates G of the group III-V semiconductor dies 12. Line 74 is a predetermined gate current level.

When the sweep signal is applied to the gates G of the group III-V semiconductor dies 12, a portion of dies with the gate currents to be smaller than a predetermined gate current is determined according to the gate current information. In some embodiments, the determined portion of dies the group III-V semiconductor dies 12 are KGDs. For example, a current level of the line L71 is determined to be smaller than the current level of the line L73 when the gate voltages are reversed biased. On the contrary, a current level of the line L72 is determined to be greater than the current level of the line L73 when the gate voltages are reversed biased. Therefore, the group III-V semiconductor die corresponding to the line L71 is determined to be KGD.

In some embodiments, the gate trapping test may be utilized to recognize a gate junction defect which occurs at the interface at which the polarization modulation portion 114 and the barrier layer 108 directly contact, in the barrier layer 108, in the polarization modulation portion 114 or at the sidewalls of the polarization modulation portion 114. In some embodiments, the gate junction defect is resulted from the pits and/or damages in the polarization modulation portion 114 and/or the barrier layer 108. And, the gate junction defect may result in abnormal gate current relationship under reversed bias gate. Therefore, the gate trapping test may effectively recognize KGDs among the group III-V semiconductor dies 12 of the semiconductor wafer 10.

In some embodiments, a gate barrier test may be performed to the group III-V semiconductor dies 12 to determine a portion of dies of the group III-V semiconductor dies 12. In some embodiments, the determined portion of dies may have their gate currents to be smaller than a predetermined gate current. The determined portion of dies may be recognized as KGDs.

Specifically, in the gate barrier test, a sweep signal is applied to the gates G of the semiconductor devices 104 in the group III-V semiconductor dies 12, to obtain a gate current information corresponding to gate currents of the semiconductor devices 104. Then, a sweep signal is applied to the drains D of semiconductor devices 104 in the group III-V semiconductor dies 12, to obtain a cutoff current information corresponding to cutoff currents of the semiconductor devices 104. The supplied sweep signal may be a voltage within a voltage range of 0V-1500V, to obtain the cutoff current information within the voltage range. In order to obtain the cutoff current, the gates G of the semiconductor devices 104 in the group III-V semiconductor dies 12 may be biased under a predetermined cutoff voltage. In some embodiments, the predetermined cutoff voltage is 0V. Then, a portion of dies with the cutoff currents to be smaller than a predetermined cutoff current may be obtained according to the cutoff current information.

FIG. 8 illustrates exemplary relationship curves of cutoff currents and drain voltages of two group III-V semiconductor dies 12 as illustrated in FIG. 1 and FIG. 2. The vertical axis is the cutoff current, and the horizontal axis is the applied drain voltage of the group III-V semiconductor dies 12. Lines L80, L81 are the relationship curves of two different group III-V semiconductor dies 12. A line L82 is a current level of the predetermined cutoff current. In some embodiments, the current level of the predetermined cutoff current is 10⁻³ A/um. Since the line L81 is below the line L82, the group III-V semiconductor die 12 corresponding to the line L81 is recognized as a KGD. In some embodiments, in the group III-V semiconductor die 12 corresponding to the line L81, the concentration of magnesium (i.e., P-type dopant) contained in the polarization modulation portion 114 ranges from about 1% to about 20%, and the concentration of aluminum contained in the barrier layer 108 ranges from about 5% to about 40%. In detail, when these concentration ranges are within the said ranges, the gate leakage current is prevented from being generated, so as to obtain improved operation controllability. That is to say, the gate barrier test may be utilized to recognize the possibility of the gate leakage current from being generated. It is noted that the thickness of the polarization modulation portion 114 and the concentration of magnesium should be considered at the same time, and also the thickness of the barrier layer 108 and the concentration of aluminum should be considered at the same time.

In some embodiments, a robustness test of drain-source breakdown voltage (BVdss) may be performed to the group III-V semiconductor dies 12 to determine a portion of dies of the group III-V semiconductor dies 12. In some embodiments, the determined portion of dies may have their slopes of drain currents to be less than predetermined slope.

Specifically, in the robustness test of BVdss, a sweep signal is applied to the drains D of the semiconductor devices 104 in the group III-V semiconductor dies 12, to obtain a drain current information corresponding to drain currents of the semiconductor devices 104. A portion of dies with slopes of the drain currents to be smaller than a predetermined slope is obtained according to the drain current information.

Specifically, in the robustness test of BVdss, a sweep signal is applied to the drains D of the semiconductor devices 104 in the group III-V semiconductor dies 12, to obtain a drain current information corresponding to drain currents of the semiconductor devices 104. The supplied sweep signal may be a voltage within a voltage range of 0V-1500V. Then, slopes of the drain currents with respect to the drain voltages are obtained through analysis, and the slopes of the drain currents are compared with the predetermined slope. A portion of dies with the slopes of the drain currents to be smaller than the predetermined slope is determined to be KGDs.

FIG. 9 illustrates exemplary relationship curves of drain currents and drain voltages of two group III-V semiconductor dies 12 as illustrated in FIG. 1 and FIG. 2. The vertical axis is the drain current, and the horizontal axis is the applied drain voltage of the group III-V semiconductor dies 12. Lines L90, L91 are respectively the relationship curves of two different group III-V semiconductor dies 12. As can be seen, the line L90 has a greater slope on the right-hand side of the figure. After analysis, since the slope of the line L90 is greater than the predetermined slope, the group III-V semiconductor die 12 corresponding to the line L90 may be recognized as a bad die. In detail, the slope of the line L90 being greater than the predetermined slope is resulted from the defects (such as V shaped-groove defect, line defect, skew defect) in the epitaxial layers (e.g., the barrier layer 108, the channel layer 106) of the group III-V semiconductor die 12. That is to say, the robustness test of BVdss may be utilized to determining whether there are defects in epitaxial layers of the group III-V semiconductor die 12. Since the slope of the line L91 is smaller than the predetermined slope, the group III-V semiconductor die 12 corresponding to the line L91 may be recognized as a KGD.

In some embodiments, an access region trap test may be performed to the group III-V semiconductor dies 12 to determine a portion of dies of the group III-V semiconductor dies 12. In some embodiments, the determined portion of dies may have their cutoff currents to be less than a predetermined cutoff current after a temperature is provided to the group III-V semiconductor dies 12.

Specifically, the access region trap test is for determining whether there is excess charge trapped after a high temperature is applied, which will further induce the cutoff current to rise. After analysis, the excess charge trapped may be resulted from the defects (e.g., pits) on the surfaces of the epitaxial layers of the group III-V semiconductor die 12. As such, the access region trap test may be utilized to determining whether there are defects at the surfaces of the epitaxial layers in the group III-V semiconductor die 12. In the access region trap test, a first temperature greater than a predetermined temperature is provided to the group III-V semiconductor dies 12. In some embodiments, the predetermined temperature is a temperature selected from a voltage range of 75-250° C. Then, stop providing the first temperature to the group III-V semiconductor dies 12. After a predetermined time when the first temperature is stopped from being provided to the group III-V semiconductor dies 12, a sweep signal is applied to drain D and source S of semiconductor devices 104 in the group III-V semiconductor dies 12 to obtain the cutoff current information corresponding to cutoff currents of the semiconductor devices 104. In some embodiments, the predetermined time may be 0.5-2 second. In some embodiments, the predetermined time may be 1 second. In some embodiments, the cutoff current information is measured while the gates G of semiconductor devices 104 are provided with 0V for the semiconductor devices 104 to be cutoff. At last, obtain a portion of dies with the cutoff current variation to be smaller than a predetermined cutoff current variation according to the cutoff current information. The cutoff current variation may be obtained through calculating a ratio between a first cutoff current and a second cutoff current. The first cutoff current may be a cutoff current obtained after high temperature is applied. The second cutoff current may be a cutoff current obtained before high temperature is applied. The portion of dies with the cutoff current variation smaller than the predetermined cutoff current variation may be determined as KGDs. In some embodiments, the predetermined cutoff current variation may be −30% to +30%.

FIG. 10 illustrates an exemplary relationship curves of cutoff currents of a group III-V semiconductor die 12 as illustrated in FIG. 1 and FIG. 2. The vertical axis is the cutoff current, and the horizontal axis is the applied voltage difference between the drain D and the source S of the group III-V semiconductor die 12. The lines L100, L101 are cutoff current curves of a same group III-V semiconductor die 12 measured under different conditions. Specifically, the line L101 is a cutoff current curve measured before the first temperature is applied. In some embodiments, the line L101 is measured under a room temperature (e.g., 25° C.). The line L100 is cutoff current curve measured after the first temperature is applied. In some embodiments, the line L100 is measured after the stopped providing the first temperature to the group III-V semiconductor die 12 for the predetermined time. Since the cutoff current variation between the lines L100 and L101 is greater than the predetermined cutoff current variation, the group III-V semiconductor die 12 may be recognized as a bad die.

In some embodiments, a BVdss acceleration test may be performed to the group III-V semiconductor dies 12 to determine a portion of dies of the group III-V semiconductor dies 12. In some embodiments, the determined portion of dies may have their second derivative of the drain currents with respect to the drain voltages to be greater than a predetermined value when a first temperature greater than a predetermined temperature is applied to the group III-V semiconductor dies 12.

Specifically, in the BVdss acceleration test, a high temperature greater than a predetermined temperature may be provided to the group III-V semiconductor dies 12. Moreover, a sweep signal may be provided to the drains D of semiconductor devices 104 in the group III-V semiconductor dies 12. A voltage level of the provided sweep signal may be selected from a voltage range of 300V-1500V. A drain current information corresponding to drain currents of the semiconductor devices 104 may be obtained. Then, second derivatives of the drain currents with respect to the drain voltages are calculated according to the drain current information. A portion of dies with the second derivatives of the drain currents with respect to the drain voltages to be greater than a predetermined value may be obtained. In some embodiments, the predetermined value may be a value selected from greater than 10⁻¹¹ A/V².

FIG. 11 illustrates calculated first derivatives and second derivatives of the group III-V semiconductor dies 12 as illustrated in FIG. 1 and FIG. 2. The dots in the lower portion are the calculated first derivatives of the drain currents with respect to the drain voltages. The dots in the upper portion are the calculated second derivatives of the drain currents with respect to the drain voltages. A line L112 is a level of the predetermined value. As can be seen, in the second derivatives, the dots D110, D111 are smaller than the predetermined value, and thus the group III-V semiconductor die 12 having the predetermined value corresponding to the dots D110, D111 is recognized as a bad die. After analysis, the second derivatives of the drain currents with respect to the drain voltages being smaller than a predetermined value may be resulted from the deep-level defects of the epitaxial layers in the group III-V semiconductor die 12. As such, during the BVdss acceleration test, by calculating second derivatives of the drain currents with respect to the drain voltages, whether there are deep-level defects of the epitaxial layers in the group III-V semiconductor die 12 may be determined.

Referring to FIG. 3 and FIGS. 12A-12C, in step S34, a singulation process is performed to the semiconductor wafer 10 so as to form individual group III-V semiconductor dies 12. In detail, the singulation process includes a first laser grooving process L1, a second laser grooving process L2 and a mechanical dicing process M, such that the stress caused during the singulation process can be released and no dislocation and crack is found in the singulated group III-V semiconductor dies 12. In other word, the singulation process includes two non-contact cutting process and one contact cutting process.

Referring to FIG. 12A, the first laser grooving process L1 is performed to the semiconductor wafer 10 along the scribe streets 14. In some embodiments, during the first laser grooving process L1 of the singulation process, a laser beam is applied to the semiconductor wafer 10 along the scribe streets 14 to form intersected grooves G1 with a predetermined depth in the scribe streets 14 without cutting through the semiconductor wafer 10. In detail, as shown in FIG. 12A, the first laser grooving process L1 is performed to cut through the interconnection structure 120, the dielectric layer 118, the passivation layer 116 and the barrier layer 108 and cut into the channel layer 106 to form the grooves G1. That is to say, the grooves G1 extend downwardly along a direction Z parallel to a normal direction of the semiconductor wafer 10 and perpendicular to the direction X and the direction Y through the interconnection structure 120, the dielectric layer 118, the passivation layer 116 and the barrier layer 108, and portions of the channel layer 106 are revealed by the grooves G1. In some embodiments, as shown in FIG. 12A, the bottom surfaces of the grooves G1 are lower than the top surface of the channel layer 106. In certain embodiments, the distance d1 between the bottom surface of the groove G1 and the top surface of the channel layer 106 is greater than 0 micrometer to approximately 5 micrometers. In some embodiments, the first laser grooving process L1 uses a laser beam with a laser power strong enough to remove the test pads (if present), test keys (if present), metal routings (if present), other dielectric layer (if present), other passivation layer (if present), the dielectric layer 118, the passivation layer 116, the barrier layer 108, and the channel layer 106 in the scribe streets 14. In one embodiment, the first laser grooving process L1 is performed with an infrared laser such as an Nd-YAG (neodymium-doped yttrium aluminum garnet) laser.

Referring to FIG. 12B, after the grooves G1 are formed, the second laser grooving process L2 is performed to the semiconductor wafer 10 along the scribe streets 14. In some embodiments, during the second laser grooving process L2 of the singulation process, a laser beam is applied to the semiconductor wafer 10 along the grooves G1 to form intersected grooves G2 with a predetermined depth in the scribe streets 14 without cutting through the semiconductor wafer 10. In detail, as shown in FIG. 12B, the second laser grooving process L2 is performed to cut through the channel layer 106 and cut into the substrate 102 to form the grooves G2. That is to say, the grooves G2 extend downwardly along the direction Z through the channel layer 106, and portions of the substrate 102 are revealed by the grooves G2. In some embodiments, as shown in FIG. 12B, the bottom surfaces of the grooves G2 are lower than the top surface of the substrate 102. In certain embodiments, the distance d2 between the bottom surface of the groove G2 and the top surface of the substrate 102 is greater than 0 micrometer to approximately 5 micrometers. In some embodiments, the groove G2 is communicated with the groove G1. In some embodiments, as shown in FIG. 12B, the sidewall of the groove G2 is aligned with the sidewall of the groove G1 from the cross-sectional view. However, the disclosure is not limited thereto. In some alternative embodiments, the groove G1 and the groove G2 under the groove G1 may have a staircase shaped profile defined by the sidewall and the bottom surface of the groove G1 and the sidewall of the groove G2. In some embodiments, the laser power of the first laser grooving process L1 is less than the laser power of the second laser grooving process L2. In some embodiments, the cutting width of first laser grooving process L1 is wider than the cutting width of the second laser grooving process L2. In one embodiment, the second laser grooving process L2 is performed with an infrared laser such as an Nd-YAG (neodymium-doped yttrium aluminum garnet) laser.

Referring to FIG. 12C, after the grooves G2 are formed, the mechanical dicing process M is performed to the semiconductor wafer 10 along the scribe streets 14. In some embodiments, the mechanical dicing process M includes a mechanical blade dicing step using a diamond embedded blade (not shown) to cut through the substrate 102 along the grooves G2 to separate the group III-V semiconductor dies 12. That is to say, as shown in FIG. 12C, after performing the mechanical dicing process M, the group III-V semiconductor dies 12 of the semiconductor wafer 10 are separate and singulated. In some embodiments, as shown in FIG. 12C, the outer sidewall of the singulated group III-V semiconductor die 12 is slanted from the cross-sectional view. However, the disclosure is not limited thereto. In some alternative embodiments, the outer sidewall of the singulated group III-V semiconductor die 12 may have a staircase shaped profile. In some embodiments, the cutting width of the second laser grooving process L2 is wider than the cutting width of the mechanical dicing process M.

The singulated group III-V semiconductor dies 12 may be additional processed or packaged in the subsequent processes, and these subsequent processes may be modified based on the product design and will not be described in details herein. Referring FIG. 3 and FIG. 13, in step S36, at least one of the singulated group III-V semiconductor dies 12 is subjected to a packaging process into an individual group III-V semiconductor package 20. In some embodiments, the group III-V semiconductor package 20 may be electrically coupled to another component through a plurality of conductive terminals 202. The another component may be or may include a package substrate, a printed circuit board (PCB), a printed wiring board, and/or other carrier that is capable of carrying integrated circuits. In some embodiments, the conductive terminals 202 are controlled collapse chip connection (C4) bumps. The conductive terminals 202 may include a conductive material such as solder, copper, aluminum, gold, nickel, silver, palladium, tin, the like, or combinations thereof. In some embodiments, the conductive terminals 202 are formed by initially forming a layer of solder through evaporation, electroplating, printing, solder transfer, ball placement, or the like. Once the layer of solder has been formed on the structure, a reflow process may be performed in order to shape the material into the desired bump shapes. In another embodiment, the conductive terminals 202 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, a position information of each of the group III-V semiconductor package 20 may be taken into consideration. The position information may correspond to where the group III-V semiconductor package 20 is located on the semiconductor wafer 10. In some embodiments, the group III-V semiconductor packages 20 are divided into several groups according to the position information. For example, the group III-V semiconductor packages 20 may be divided several groups according to their distance to the center of the wafer 10. In some embodiments, each of the group III-V semiconductor package 20 may be marked with a serial number outside the packaging, and thus the position information of each of the group III-V semiconductor package 20 may be carried in the serial number. In some embodiments, a good die fully or partially surrounded by bad dies (aka, good die in bad cluster (GDBC)) can also be recognized as a bad die.

Referring FIG. 3, in step S38, the group III-V semiconductor package 20 is subjected to a final testing process.

In the final testing process, a multilevel breakdown voltage test may be performed to the group III-V semiconductor package 20. Specifically, in the multi-step breakdown voltage test, a first sweep signal may be applied to the drains D of the semiconductor devices 104 in the group III-V semiconductor package 20 to determine a first portion of dies with drain currents to be smaller a predetermined breakdown current. The first sweep signal may be increased gradually up to a first voltage level. In some embodiments, the dies with drain currents to be greater than the predetermined breakdown current may be recognized as bad dies, and the first portion of dies with the drain currents to be smaller the predetermined breakdown current may be obtained. In some embodiments, the first voltage level is selected from a voltage range within 0V-1500V. The predetermined breakdown current level is selected from a current range within 10 mA-10 nA. Then, a second sweep signal may be applied to the drain D of the first portion of dies, and a second portion of dies of the group III-V semiconductor package 20 with the drain currents to be smaller than the predetermined breakdown current is obtained. The second sweep signal may be increased gradually up to a second voltage level. In some embodiments, the second voltage level is selected from a voltage range within 300V-1500V. The first voltage level is greater than the second voltage level. Therefore, the second portion of dies which keep their drain currents to be less than the predetermined breakdown current while applying the first sweep signal and the second sweep signal are obtained. In some embodiments, the second portion of dies may be determined as KGDs.

The epitaxial layers (e.g., the barrier layer 108, the channel layer 106) of the group III-V semiconductor die 12 are sensitive to the stress caused during the singulation process, and thus the defects (e.g., cracks, dislocations) are usually formed in the epitaxial layers to affect the reliability, the device operation voltage and the yield of the group III-V semiconductor die 12. As such, in the above embodiments, as the singulation process includes two steps of laser grooving processes and one step of mechanical dicing process, the stress caused during the singulation process can be released, thus leading to no dislocation and crack found in the group III-V semiconductor dies.

In accordance with an embodiment, a manufacturing method of group III-V semiconductor package includes: providing a wafer comprising group III-V semiconductor dies therein; performing a chip probing (CP) process to the wafer to determine reliabilities of the group III-V semiconductor dies, wherein the CP process comprises: performing a multi-step breakdown voltage testing process to the group III-V semiconductor dies to obtain a first portion of dies of the group III-V semiconductor dies with breakdown voltages to be smaller than a predetermined breakdown voltage; performing a singulation process to separate the group III-V semiconductor dies from the wafer; performing a package process to form group III-V semiconductor packages including the group III-V semiconductor dies; and performing a final testing process on the group III-V semiconductor packages.

In accordance with an embodiment, a manufacturing method of group III-V semiconductor package includes: providing a wafer comprising group III-V semiconductor dies therein; performing a wafer testing process to the wafer; performing a singulation process to separate the group III-V semiconductor dies from the wafer, wherein the singulation process comprises a first laser grooving process, a second laser grooving process and a mechanical dicing process; packaging the separated group III-V semiconductor dies to form group III-V semiconductor packages; and performing a final testing process on the group III-V semiconductor packages.

In accordance with an embodiment, a manufacturing method of group III-V semiconductor package includes: providing a wafer having group III-V semiconductor dies and scribe streets surrounding the group III-V semiconductor dies and between the group III-V semiconductor dies; performing a wafer testing process to the wafer; performing a first laser grooving process to the wafer along the scribe streets; performing a second laser grooving process to the wafer along the scribe streets; performing a mechanical dicing process cutting through the wafer along the scribe streets to singulate the group III-V semiconductor dies; and packaging the singulated group III-V semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of group III-V semiconductor package, comprising:
providing a wafer comprising group III-V semiconductor dies therein;
performing a chip probing (CP) process to the wafer to determine reliabilities of the group III-V semiconductor dies, wherein the CP process comprises:
performing a multi-step breakdown voltage testing process to the group III-V semiconductor dies to obtain a first portion of dies of the group III-V semiconductor dies with breakdown voltages to be smaller than a predetermined breakdown voltage;
performing a singulation process to separate the group III-V semiconductor dies from the wafer;
performing a package process to form group III-V semiconductor packages including the group III-V semiconductor dies; and
performing a final testing process on the group III-V semiconductor packages.

2. The manufacturing method of claim 1, wherein performing the multi-step breakdown voltage testing process to the group III-V semiconductor dies comprises:
applying a first sweep signal to drain terminals of transistors in the group III-V semiconductor dies to determine the first portion of dies of the group III-V semiconductor dies with drain currents to be smaller a predetermined breakdown current; and
applying a second sweep signal to the drain terminals of the first portion of dies, to determine a second portion of dies of the group III-V semiconductor dies with the drain currents to be smaller than the predetermined breakdown current,
wherein the first sweep signal is increased up to a first voltage level, the second sweep signal is increased up to a second voltage level, the first voltage level is greater than the second voltage level,
wherein the first voltage is greater than the second voltage.

3. The manufacturing method of claim 1, wherein performing the CP testing process comprises:
performing a high temperature reverse bias (HTRB) testing process to the group III-V semiconductor dies to obtain a drain current variation information of drain current variations of transistors in the group III-V semiconductor dies; and
obtaining a second portion of dies with the drain current variations to be within a predetermined current variation range according to the drain current variation information.

4. The manufacturing method of claim 1, wherein performing the CP testing process comprises:
performing a substrate leakage testing process to the group III-V semiconductor dies to obtain a second portion of dies of the group III-V semiconductor dies with substrate leakage currents to be smaller than a predetermined substrate leakage current.

5. The manufacturing method of claim 4, wherein performing the substrate leakage testing process to the group III-V semiconductor dies comprises:
applying a sweep signal to drain terminals of transistor in the group III-V semiconductor dies, to obtain a substrate leakage current information of the group III-V semiconductor dies; and
obtaining the second portion of dies with the substrate leakage currents to be smaller than the predetermined substrate leakage current according to the substrate leakage current information.

6. The manufacturing method of claim 1, wherein performing the CP testing process comprises:
applying a sweep signal to gate terminals of transistors in the group III-V semiconductor dies, to obtain a gate current information corresponding to gate currents of the transistors; and
obtaining a second portion of dies with the gate currents to be smaller than a predetermined gate current according to the gate current information.

7. The manufacturing method of claim 1, wherein performing the CP testing process comprises:
applying a sweep signal to drain terminals of transistors in the group III-V semiconductor dies, to obtain a cutoff current information corresponding to cutoff currents of the transistors; and
obtaining a second portion of dies with the cutoff currents to be smaller than a predetermined cutoff current according to the cutoff current information.

8. The manufacturing method of claim 1, wherein performing the CP testing process comprises:
applying a sweep signal to drain terminals of transistors in the group III-V semiconductor dies, to obtain a drain current information corresponding to drain currents of the transistors; and
obtaining a second portion of dies with slopes the drain currents to be smaller than a predetermined slope according to the drain current information.

9. The manufacturing method of claim 1, wherein performing the CP testing process comprises:
providing a first temperature greater than a predetermined temperature to the group III-V semiconductor dies;
after stopped providing the first temperature to the group III-V semiconductor dies for a predetermined time, applying a sweep signal to drain and source terminals of transistors in the group III-V semiconductor dies to obtain a cutoff current information corresponding to cutoff currents of the transistors; and
obtaining a second portion of dies with the cutoff current variation to be smaller than a predetermined cutoff current variation according to the cutoff current information.

10. The manufacturing method of claim 1, wherein performing the CP testing process comprises:
applying a first temperature greater than a predetermined temperature to the group III-V semiconductor dies;
applying a first voltage level to drain terminals of transistors in the group III-V semiconductor dies to obtain a drain current information corresponding to drain currents of the transistors;
calculating second derivatives of the drain currents according to the drain current information; and
obtaining a second portion of dies with the second derivatives of the drain currents to be greater than a predetermined value.

11. A manufacturing method of group III-V semiconductor package, comprising:
providing a wafer comprising group III-V semiconductor dies therein;
performing a wafer testing process to the wafer;
performing a singulation process to separate the group III-V semiconductor dies from the wafer, wherein the singulation process comprises a first laser grooving process, a second laser grooving process and a mechanical dicing process;
packaging the separated group III-V semiconductor dies to form group III-V semiconductor packages; and
performing a final testing process on the group III-V semiconductor packages.

12. The manufacturing method of claim 11, wherein a laser power of the first laser grooving process is less than a laser power of the second laser grooving process.

13. The manufacturing method of claim 11, wherein the second laser grooving process is performed after the first laser grooving process is performed, and the mechanical dicing process is performed after the second laser grooving process is performed.

14. The manufacturing method of claim 11, wherein the step of performing the final testing process comprises performing a multiple-step breakdown voltage testing process on the group III-V semiconductor packages.

15. A manufacturing method of group III-V semiconductor package, comprising:
providing a wafer having group III-V semiconductor dies and scribe streets surrounding the group III-V semiconductor dies and between the group III-V semiconductor dies;
performing a wafer testing process to the wafer;
performing a first laser grooving process to the wafer along the scribe streets;
performing a second laser grooving process to the wafer along the scribe streets;
performing a mechanical dicing process cutting through the wafer along the scribe streets to singulate the group III-V semiconductor dies; and
packaging the singulated group III-V semiconductor dies.

16. The manufacturing method of claim 15, wherein providing the wafer having the group III-V semiconductor dies and the scribe streets comprises sequentially forming a channel layer and a barrier layer over a substrate.

17. The manufacturing method of claim 16, wherein the first laser grooving process is performed to cut through the barrier layer and cut into the channel layer to form first grooves, and bottom surfaces of the first grooves are lower than a top surface of the channel layer.

18. The manufacturing method of claim 17, wherein the second laser grooving process is performed along the first grooves to cut through the channel layer and cut into the substrate to form second grooves, and bottom surfaces of the second grooves are lower than a top surface of the substrate.

19. The manufacturing method of claim 18, wherein the mechanical dicing process is performed to along the second grooves to cut through the substrate.

20. The manufacturing method of claim 19, wherein a cutting width of first laser grooving process is wider than a cutting width of the second laser grooving process, and the cutting width of the second laser grooving process is wider than a cutting width of the mechanical dicing process.
